(19) United States
(12) Patent Application Publication
(10) Pub. No.: US 2015/0108442 A1
(43) Pub. Date: Apr. 23, 2015

(54) ORGANIC LIGHT-EMITTING APPARATUS AND METHOD OF MANUFACTURING THE SAME

(71) Applicant: SAMSUNG DISPLAY CO., LTD., YONGIN-CITY (KR)

(72) Inventors: Jae-Hyun KIM, Yongin-City (KR); Myung-Soo HUH, Yongin-City (KR)

(21) Appl. No.: 14/308,804

(22) Filed: Jun. 19, 2014

(30) Foreign Application Priority Data
Oct. 17, 2013 (KR) 10-2013-0124144

(51) Int. Cl. H01L 51/52; H01L 21/56; H01L 51/56

(52) U.S. Cl. CPC H01L 51/5237; H01L 51/56; H01L 21/56
USPC 257/40; 438/26

(57) ABSTRACT

Provided is an organic light-emitting apparatus. The organic light-emitting apparatus includes: a substrate; an organic light-emitting device provided on the substrate and including a first electrode, a second electrode, and an intermediate layer provided between the first electrode and the second electrode; and an encapsulation layer provided to cover the organic light-emitting device, wherein the encapsulation layer includes a first organic layer and a first inorganic layer provided on the first organic layer and including carbon, and a carbon content of the first inorganic layer gradually decreases from an interface between the first organic layer and the first inorganic layer in a direction from the first organic layer to the first inorganic layer.

### CROSS-REFERENCE TO RELATED APPLICATION

Korean Patent Application No. 10-2013-0124144, filed on Oct. 17, 2013, in the Korean Intellectual Property Office, and entitled: “ORGANIC LIGHT-EMITTING APPARATUS AND METHOD OF MANUFACTURING THE SAME,” is incorporated by reference herein in its entirety.

### BACKGROUND

1. Field

One or more embodiments relate to organic light-emitting apparatuses and methods of manufacturing the same.

2. Description of the Related Art

An organic light-emitting device is a self-luminescent display device that emits light by electrically exciting a fluorescent organic compound. Since the organic light-emitting device may be driven at a low voltage, be formed with a small thickness, and have a wide viewing angle and a high response speed, it is a possible next-generation display device that may avoid problems associated with liquid crystal display (LCD) devices.

### SUMMARY

Embodiments may be realized by providing an organic light-emitting apparatus, including a substrate; an organic light-emitting device provided on the substrate and including a first electrode, a second electrode, and an intermediate layer provided between the first electrode and the second electrode; and an encapsulation layer provided to cover the organic light-emitting device, the encapsulation layer including a first organic layer, and including a first inorganic layer provided on the first organic layer and including carbon, a carbon content of the first inorganic layer gradually decreasing from an interface between the first organic layer and the first inorganic layer in a direction from the first organic layer to the first inorganic layer.

The carbon content of the first inorganic layer may range from about 0.1% to about 12%.

A Young's modulus of the first inorganic layer may gradually increase from the interface between the first organic layer and the first inorganic layer in the direction from the first organic layer to the first inorganic layer.

The Young's modulus of the first inorganic layer may be about 110 GPa to about 1000 GPa.

A density of the first inorganic layer may gradually increase from the interface between the first organic layer and the first inorganic layer in the direction from the first organic layer to the first inorganic layer.

A thickness of the first inorganic layer may be about 50 nm or less.

The encapsulation layer may further include a second organic layer provided on the first inorganic layer; and a second inorganic layer provided on the second organic layer and including carbon, a carbon content of the second inorganic layer gradually decreasing from an interface between the second organic layer and the second inorganic layer in a direction from the second organic layer to the second inorganic layer.

A thickness of the second inorganic layer may be about 50 nm or less.

The first inorganic layer may include AlOₓ, SiNₓ, SiOₓ, SiCₓ, SiOₓN_{y}, or a polysilazane.

The first inorganic layer may be formed by an atomic layer deposition (ALD) process.

The organic light-emitting apparatus may further include a protection layer provided between the organic light-emitting device and the encapsulation layer.

Embodiments may be realized by providing a method of manufacturing an organic light-emitting apparatus, including preparing a substrate provided with an organic light-emitting device including a first electrode, a second electrode, and an intermediate layer provided between the first electrode and the second electrode; and forming an encapsulation layer to cover the organic light-emitting device, the forming of the encapsulation layer including forming a first organic layer to cover the organic light-emitting device; and forming a first inorganic layer including carbon on the first organic layer, a carbon content of the first inorganic layer gradually decreasing from an interface between the first organic layer and the first inorganic layer in a direction from the first organic layer to the first inorganic layer.

The carbon content of the first inorganic layer may range from about 0.1% to about 12%.

A Young's modulus of the first inorganic layer may gradually increase from the interface between the first organic layer and the first inorganic layer in the direction from the first organic layer to the first inorganic layer.

A thickness of the first inorganic layer may be about 50 nm or less

The first inorganic layer may be formed by an atomic layer deposition (ALD) process.

The ALD process may include a cycling process of an adsorption operation, a first exhaust operation, a reaction operation, and a second exhaust operation.

The carbon content of the first inorganic layer may be controlled in the reaction operation.

The method may further include controlling a reaction time in the reaction operation

The first inorganic layer may be formed by a plasma-enhanced chemical vapor deposition (PECVD) process.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of an organic light-emitting apparatus according to an embodiment;

FIG. 2 illustrates a cross-sectional view of an organic light-emitting apparatus according to another embodiment; and

FIGS. 3 to 11 are schematic cross-sectional views illustrating a method of manufacturing the organic light-emitting apparatus of FIG. 1, according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

As used herein, expressions such as “at least one of,” when preceding a list of elements, modify the entire list of elements and do not modify the individual elements of the list.

It will be understood that although the terms “first”, “second”, etc. may be used herein to describe various components, these components should not be limited by these terms. These terms are only used to distinguish one component from another.

As used herein, the singular forms “a”, “an” and “the” are intended to include the plural forms as well, unless the context clearly indicates otherwise.

It will be further understood that the terms “comprise”, “include” and “have” used herein specify the presence of stated features or components, but do not preclude the presence or addition of one or more other features or components.

It will be understood that when a layer, region, or component is referred to as being “formed on” another layer, region, or component, it may be directly or indirectly formed on the other layer, region, or component. That is, for example, intervening layers, regions, or components may be present.

Sizes of components in the drawings may be exaggerated for convenience of description. In other words, since sizes and thicknesses of components in the drawings are arbitrarily illustrated for convenience of description, the following embodiments are not limited thereto.

Hereinafter, exemplary embodiments will be described in detail with reference to the accompanying drawings.

FIG. 1 is a cross-sectional view of an organic light-emitting apparatus 10 according to an embodiment. Referring to FIG. 1, the organic light-emitting apparatus 10 includes an organic light-emitting device 120 disposed on a substrate 110 and including a first electrode 121, an intermediate layer 122, and a second electrode 123, and includes an encapsulation layer 130 covering the organic light-emitting device 120. The encapsulation layer 130 has a structure in which at least a first organic layer 131 and a first inorganic layer 132 are sequentially stacked.

The substrate 110 may be a substrate appropriate for use in an organic light-emitting device. For example, the substrate 110 may be a glass substrate or a plastic substrate that has excellent mechanical strength, thermal stability, transparency, surface smoothness, handleability, and waterproofness. Although not illustrated in FIG. 1, as an example of various modifications, a planarization layer and an insulating layer may be further provided on the substrate 110.

The organic light-emitting device 120 is provided on the substrate 110. The organic light-emitting device 120 includes the first electrode 121, the intermediate layer 122, and the second electrode 123.

The first electrode 121 may be formed by vacuum deposition or sputtering, and may be a cathode or an anode. The first electrode 21 may be a transparent electrode, a semitransparent electrode, or a reflective electrode, and may be formed of, for example, indium tin oxide (ITO), indium zinc oxide (IZO), tin oxide (SnO₂), zinc oxide (ZnO), aluminum (Al), silver (Ag), or magnesium (Mg). Also, as an example of various modifications, the first electrode 121 may have a two or more-layered structure using two or more different materials.

The second electrode 123 may be formed by vacuum deposition or sputtering, and may be a cathode or an anode. The second electrode 123 may be formed of a metal having a low work function, an alloy, a conductive compound, or a mixture thereof. For example, the second electrode 123 may be formed of lithium (Li), magnesium (Mg), aluminum (Al), aluminum-lithium (Al—Li), calcium (Ca), magnesium-indium (Mg—In), or magnesium-silver (Mg—Ag). Also, as an example of various modifications, the second electrode 123 may have a two or more-layered structure using two or more different materials.

The intermediate layer 122 is provided between the first electrode 121 and the second electrode 123. The intermediate layer 122 includes an organic emission layer. The intermediate layer 122 may further include other various functional layers, for example, at least one of a hole injection layer (HIL), a hole transport layer (HTL), an electron transport layer (ETL), and an electron injection layer (EIL).

A protection layer 140 may be further provided on the organic light-emitting device 120. The protection layer 140 may be formed of an organic material or an inorganic material that may prevent the second electrode 123 of the organic light-emitting device 120 from being oxidized by moisture and oxygen. Also, as an example of various modifications, the protection layer 140 may be formed of a compound of an organic material and an inorganic material.

Referring to FIG. 1, the encapsulation layer 130 is provided to cover the organic light-emitting device 120, and includes the first organic layer 131 and the first inorganic layer 132.

The first organic layer 131 may include at least one material selected from the group of acryl-based resin, methacryl-based resin, polyisoprene-based resin, vinyl-based resin, epoxy-based resin, urethane-based resin, cellulose-based resin, and parylene-based resin.

The first inorganic layer 132 is formed on the first organic layer 131. Accordingly, an interface B1 is formed between the first organic layer 131 and the first inorganic layer 132. The first inorganic layer 132 may include AlOₓ, SiNₓ, SiOₓ, SiCₓ, SiOₓN_{y}, or polysilazanes. The first inorganic layer 132 may include carbon 1321. The content of the carbon 1321 of the first inorganic layer 132 may range from about 0.1% to about 12%. The content of the carbon 1321 of the first inorganic layer 132 may gradually decrease from the interface B1 in a direction D1 from the first organic layer 131 to the first inorganic layer 132. The content of the carbon 1321 of the first inorganic layer 132 may gradually decrease from the interface B1 in a direction D1 from the first organic layer 131 to the first inorganic layer 132, and a Young's modulus of the first inorganic layer 132 may gradually increase from the interface B1 in a direction D1 from the first organic layer 131 to the first inorganic layer 132. The Young's modulus of the first inorganic layer 132 may be about 110 GPa to about 1000 GPa. The content of the carbon 1321 of the first inorganic layer 132 may gradually decrease from the interface B1 in a direction D1 from the first organic layer 131 to the first inorganic layer 132, and a density of the first inorganic layer 132 may gradually increase from the interface B1 in a direction D1 from the first organic layer 131 to the first inorganic layer 132. For example, when the first inorganic layer 132 is formed of AlOₓ and has a thickness of about 50 nm, the carbon content of the first inorganic layer 132 may be about 5%, and the density of the first inorganic layer 132 may be about 2.8 g/cm³. When the carbon content of the first inorganic layer 132 is about 1%, the density of the first inorganic layer 132 may be about 3.2 g/cm³. The content of the carbon 1321 of the first inorganic layer 132 may gradually decrease from the interface B1 in the direction D1 from the first organic layer 131 to the first inorganic layer 132, and the Young's modulus and the density of the first inorganic layer 132 may gradually increase from the interface B1 in the direction D1 from the first organic layer 131 to the first inorganic layer 132.

A sudden composition change may be present at a general interface between an organic layer and an inorganic layer when the organic layer is formed of a material having a low strength, and the inorganic layer is formed of a material having a high strength. Accordingly, a stress concentration may occur at the interface therebetween, and when the organic layer and the inorganic layer are bent, a crack or a delamination may occur, for example, starting at the interface.

According to the present embodiment, the content of the carbon 1321 of the first inorganic layer 132 may gradually decrease from the interface B1 in a direction D1 from the first organic layer 131 to the first inorganic layer 132. Thus, a sudden composition change at the interface B1 between the first organic layer 131 and the first inorganic layer 132 may be reduced or prevented. Accordingly, a stress concentration at the interface may be prevented when the encapsulation layer 130 is bent, and the possibility of a crack forming or a delamination occurring may be reduced.

Interlayer adhesion may be an important factor in the prevention of delamination of the first inorganic layer 132, for example, from the first organic layer 131. A critical adhesion exists between the layers in the encapsulation layer 130. The critical adhesion is a critical value of the interlayer adhesion. When the interlayer adhesion is smaller than the critical adhesion, interlayer delamination may occur. By minimizing the interlayer critical adhesion, delamination of the first inorganic layer and the first organic layer may be prevented.

For example, the critical adhesion between an organic layer and an inorganic layer may be about 0.7 N/m to about 0.95 N/m. A thickness H1 of the first inorganic layer 132 may be about 50 nm or less. According to the present embodiment, the critical adhesion between the first organic layer 131 and the first inorganic layer 132 may be reduced to about 0.3 N/m. Also, when the thickness of the first inorganic layer 132 is about 2.5 nm or less, the critical adhesion between the first organic layer 131 and the first inorganic layer 132 may be reduced to about 0.05 N/m or less. Thus, the critical adhesion between the first organic layer 131 and the first inorganic layer 132 may be reduced, and delamination of the first organic layer 131 and the first inorganic layer 132 may be prevented.

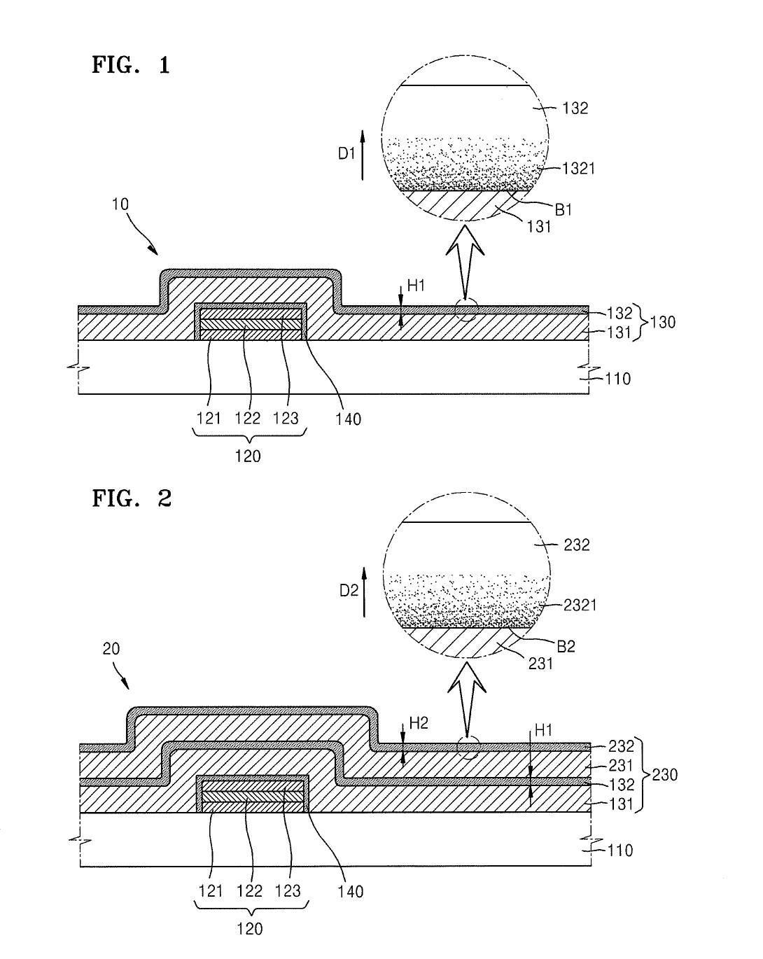

FIG. 2 is a cross-sectional view of an organic light-emitting apparatus 20 according to another embodiment.

Hereinafter, the present embodiment will be described focusing on a difference from the embodiment of FIG. 1. Herein, like reference numerals denote like elements throughout FIGS. 1 and 2.

Referring to FIG. 2, the organic light-emitting apparatus 20 includes an organic light-emitting device 120 disposed on a substrate 110 and including a first electrode 121, an intermediate layer 122, and a second electrode 123, and includes an encapsulation layer 230 covering the organic light-emitting device 120. The encapsulation layer 230 has a structure in which at least a first organic layer 131, a first inorganic layer 132, a second organic layer 231, and a second inorganic layer 232 are sequentially stacked. The first inorganic layer 132 includes carbon. The carbon content of the first inorganic layer 132 gradually decreases from the interface between the first organic layer 131 and the first inorganic layer 132 in the direction from the first organic layer 131 to the first inorganic layer 132. The second inorganic layer 232 includes carbon 2321. The carbon 2321 content of the second inorganic layer 232 gradually decreases from an interface B2 between the second organic layer 231 and the second inorganic layer 232 in the direction from the second organic layer 231 to the second inorganic layer 232.

The first organic layer 131 and the first inorganic layer 132 are the same as described with reference to FIG. 1.

The second inorganic layer 232 is formed on the second organic layer 231. Accordingly, an interface B2 is formed between the second organic layer 231 and the second inorganic layer 232. The second inorganic layer 232 may include AlOₓ, SiNₓ, SiOₓ, SiCₓ, SiOₓN_{y}, or polysilazanes. The second inorganic layer 232 may include carbon 2321. The content of the carbon 2321 of the second inorganic layer 232 may range from about 0.1% to about 12%. The content of the carbon 2321 of the second inorganic layer 232 may gradually decrease from the interface B2 in a direction D2 from the second organic layer 231 to the second inorganic layer 232. The content of the carbon 2321 of the second inorganic layer 232 may gradually decrease from the interface B2 in the direction D2 from the second organic layer 231 to the second inorganic layer 232, and the Young's modulus and the density of the second inorganic layer 232 may gradually increase from the interface B2 in the direction D2 from the second organic layer 231 to the second inorganic layer 232.

According to the present embodiment, the content of the carbon 2321 of the second inorganic layer 232 may gradually decrease from the interface B2, and a sudden composition change at the interface B2 between the second organic layer 231 and the second inorganic layer 232 may be prevented. Accordingly, a stress concentration at the interface may be prevented when the encapsulation layer 230 is bent, and the possibility of a crack forming or a delamination occurring may be reduced

A thickness H2 of the second inorganic layer 232 may be about 50 nm or less. Thus, the critical adhesion between the second organic layer 231 and the second inorganic layer 232 may be reduced, and delamination of the second organic layer 231 and the second inorganic layer 232 may be prevented.

The encapsulation layer 230 may further include a plurality of additional organic layers and inorganic layers that are alternately disposed. Herein, the number of stacked organic layers and inorganic layers is not limited.

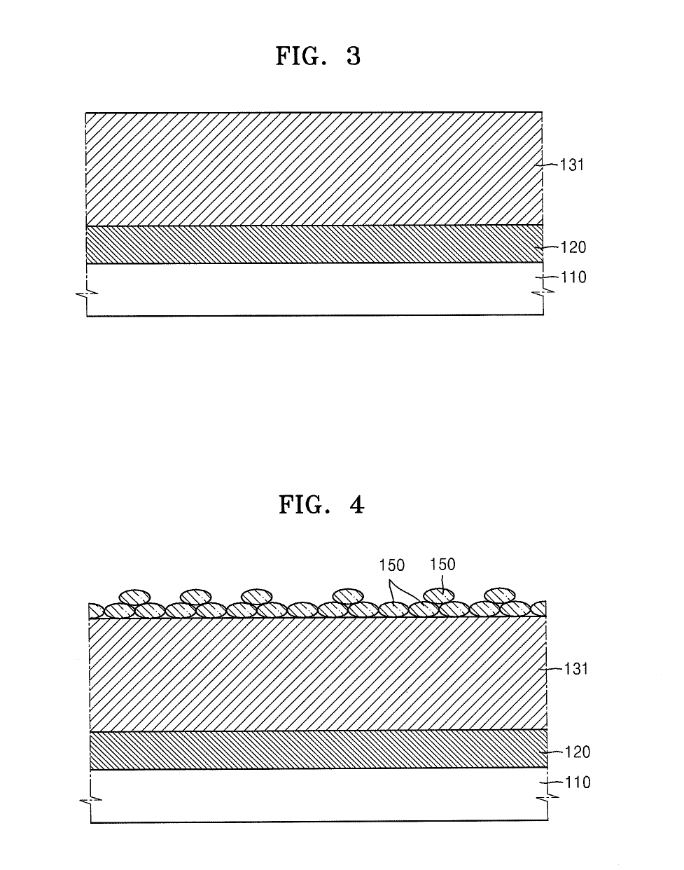

FIGS. 3 to 11 are schematic cross-sectional views illustrating a method of manufacturing the organic light-emitting apparatus 10 of FIG. 1, according to an embodiment.

Referring to FIG. 3, an organic light-emitting device 120 and a first organic layer 131 may be formed on a substrate 110.

Thereafter, an adsorption operation of an ALD process may be performed as illustrated in FIG. 4. The ALD process is a process of forming a layer at 1-monolayer level by physical adsorption. Referring to FIG. 4, a source material 150 may be adsorbed on the first organic layer 131. The source material 150 may be trimethylaluminum (TMA). One or more layers of the source material 150 may be formed.

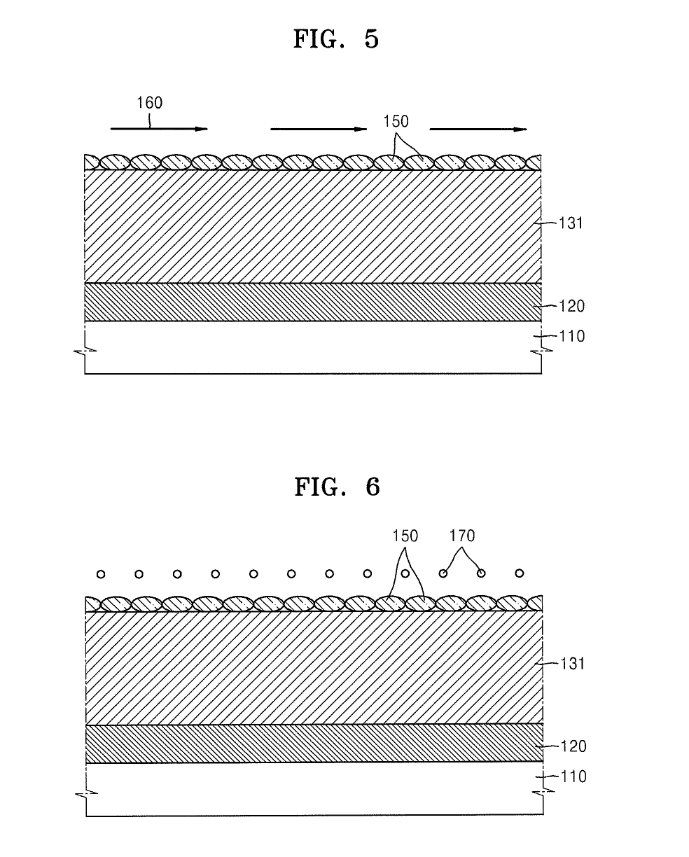

Thereafter, a first exhaust operation of the ALD process may be performed as illustrated in FIG. 5. In the first exhaust operation, exhaust gas 160 may be supplied to discharge the source material 150 that is not adsorbed by the first organic layer 131. Accordingly, one layer of the source material 150 may be formed on the first organic layer 131. Argon (Ar) may be used as the exhaust gas 160.

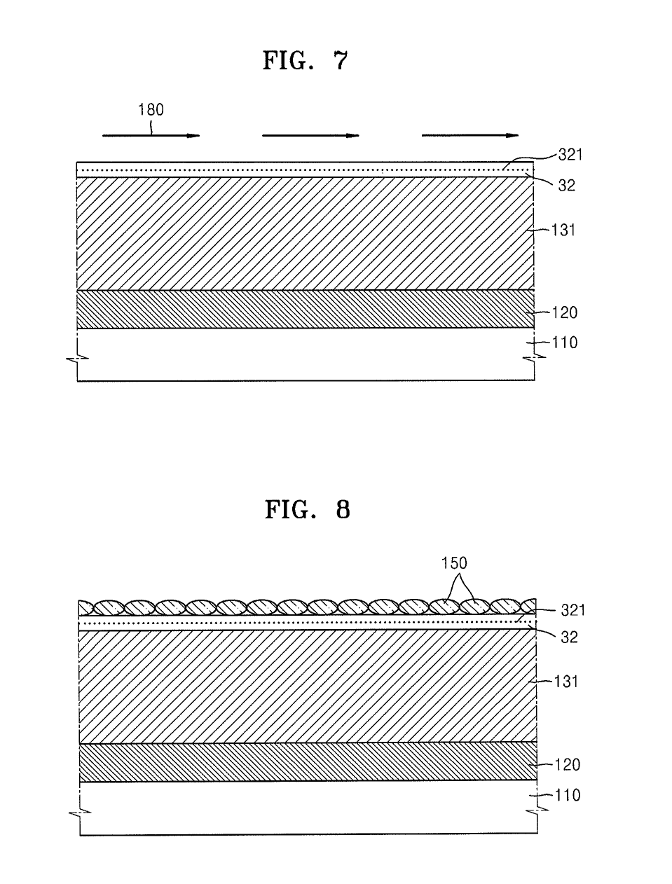

Thereafter, a reaction operation of the ALD process may be performed as illustrated in FIG. 6. Referring to FIG. 6, a reactive material 170 may be supplied. The source material 150 reacts with the reactive material 170, and a lower inorganic layer 32 may be formed as illustrated in FIG. 7. When the reactive material 170 is supplied, plasma, heat, or ultraviolet rays may be applied as an energy source. The source material 150 may react with the reactive material 170 for a predetermined reaction time T1. The reactive material 170 may be active oxygen. When the source material 150 is TMA and the reactive material 170 is active oxygen, the TMA may react with the active oxygen, and an AlOₓ layer may be formed as the lower inorganic layer 32. In this case, the carbon included in the TMA is unstably combined with the AlOₓ, and the lower inorganic layer 32 may include carbon 321.

Thereafter, a second exhaust operation of the ALD process may be performed as illustrated in FIG. 7. In the second exhaust operation, exhaust gas 180 may be supplied to discharge materials other than the lower inorganic layer 32. Argon (Ar) may be used as the exhaust gas 180.

The ALD process may include a cycling process of the adsorption operation, the first exhaust operation, the reaction operation, and the second exhaust operation. The adsorption operation and the first exhaust operation of the ALD process may be performed as illustrated in FIG. 8. Accordingly, one layer of the source material 150 may be formed on the lower inorganic layer 32.

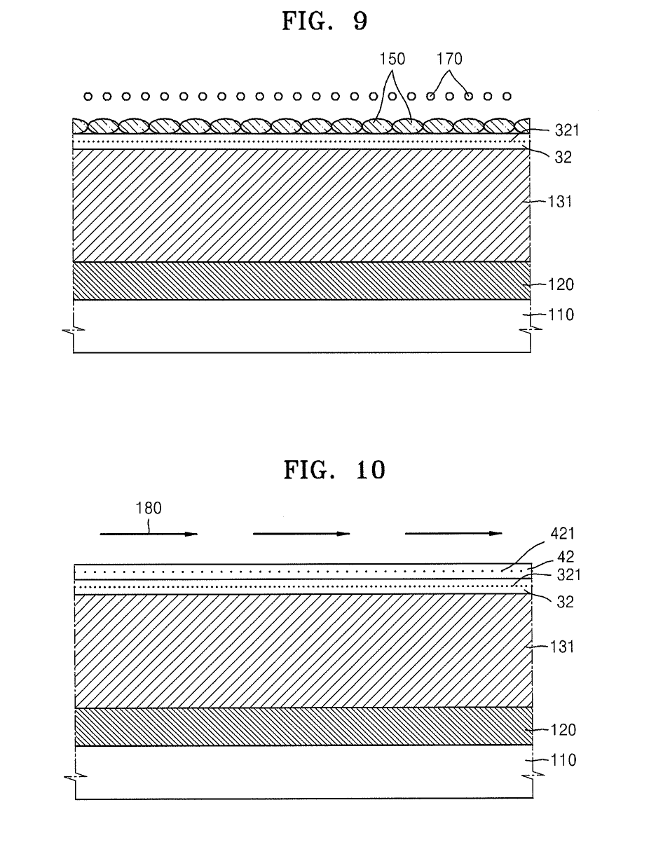

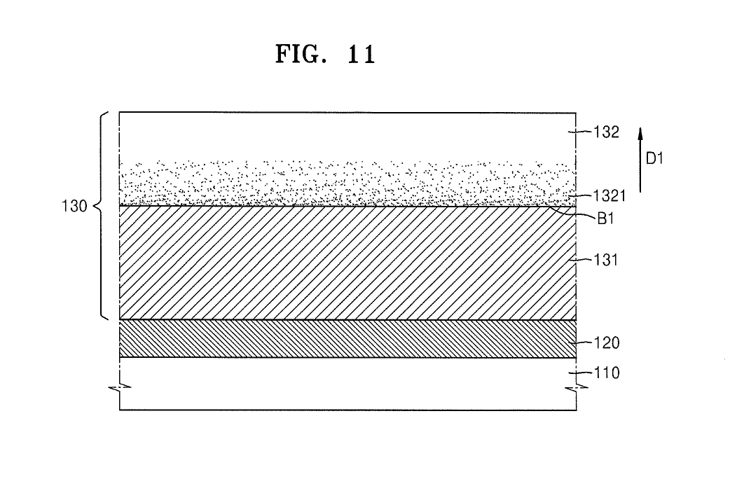

Thereafter, the reaction operation of the ALD process may be performed as illustrated in FIG. 9. Referring to FIG. 9, a reactive material 170 may be supplied. The source material 150 may react with the reactive material 170, and an upper inorganic layer 42 may be formed as illustrated in FIG. 10. When the reactive material 170 is supplied, plasma, heat, or ultraviolet rays may be applied as an energy source. The source material 150 may react with the reactive material 170 for a predetermined reaction time T2. T2 may be greater than T1. The reactive material 170 may be active oxygen. When the source material 150 is TMA and the reactive material 170 is active oxygen, the TMA may react with the active oxygen, and an AlOₓ layer may be formed as the upper inorganic layer 42. In this case, the carbon included in the TMA is unstably combined with the AlOₓ, and the upper inorganic layer 42 may include carbon 421. Since the carbon is unstably combined with the AlOₓ, as the reaction time is increased, the unstably-combined carbon may be separated from the AlOₓ by reacting with the active oxygen. Accordingly, the carbon 421 content of the upper inorganic layer 42 may be reduced. Thus, when the reaction time T2 for forming the upper inorganic layer 42 is set to be longer than the reaction time T1 for forming the lower inorganic layer 32, the carbon 421 content of the upper inorganic layer 42 may be smaller than the carbon 321 content of the lower inorganic layer 32. Subsequent cycles may sequentially increase the reaction time. In this way, by forming the organic layer, as illustrated in FIG. 11, the first inorganic layer 132 may be formed such that the carbon 1321 content gradually decreases from the interface B1 between the first organic layer 131 and the first inorganic layer 132 in the direction D1 from the first organic layer 131 to the first inorganic layer 132. Accordingly, a sudden composition change at the interface B1 between the first organic layer 131 and the first inorganic layer 132 may be reduced or prevented. Thus, a stress concentration at the interface may be prevented when the encapsulation layer 130 is bent, and the possibility of a crack forming or a delamination occurring may be reduced.

A thickness H1 of the first inorganic layer 132 may be about 50 nm or less. Accordingly, the critical adhesion between the first organic layer 131 and the first inorganic layer 132 may be reduced, and delamination of the first organic layer 131 and the first inorganic layer 132 may be prevented.

When the first inorganic layer 132 includes polysilazanes, plasma-enhanced chemical vapor deposition (PECVD) may be applied to form the first inorganic layer 132. In this case, by controlling the partial pressure of oxygen, the first inorganic layer 132 may have a gradient carbon content.

As described above, according to the one or more of the above embodiments, the durability of the encapsulation layer in the organic light-emitting apparatuses may be improved.

By way of summation and review an embodiment relates to an organic light-emitting apparatus and a method of manufacturing the same, and more particularly, to an organic light-emitting apparatus including an organic layer, an inorganic layer, and an intermixing region disposed at an interface between the organic layer and the inorganic layer and including an organic material constituting the organic layer and an inorganic material constituting the inorganic layer, and a method of manufacturing the same. An encapsulation layer of the organic light-emitting apparatus has excellent oxygen-proof performance and moisture-proof performance and may be formed as an ultrathin film, and the organic light-emitting apparatus may have a long life and high brightness. Also, the method of manufacturing the organic light-emitting apparatus is simple, and the manufacturing cost thereof may be reduced.

The organic light-emitting device includes an intermediate layer that is disposed between an anode electrode and a cathode electrode and is formed of an organic material. When a positive voltage and a negative voltage are applied to the anode electrode and the cathode electrode, respectively, of the organic light-emitting device, holes injected from the anode electrode may pass via a hole transport layer to the intermediate layer, and electrons may pass via an electron transport layer to the intermediate layer. The holes and the electrons are recombined with each other in the intermediate layer to generate excitons.

Then, the excitons are transitioned from an excited state to a ground state, and fluorescent molecules of the intermediate layer emit light, thereby forming an image. A full-color organic light-emitting device implements full colors by using pixels that emit three colors of red (R), green (G) and blue (B).

As described above, the organic light-emitting device includes the cathode electrode contacting the organic layer. In order to improve the reliability of the organic light-emitting device, the organic light-emitting device may be protected from moisture permeation and oxygen permeation.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting apparatus, comprising:
a substrate;
an organic light-emitting device provided on the substrate and including a first electrode, a second electrode, and an intermediate layer provided between the first electrode and the second electrode; and
an encapsulation layer provided to cover the organic light-emitting device, the encapsulation layer including a first organic layer, and including a first inorganic layer provided on the first organic layer and including carbon, a carbon content of the first inorganic layer gradually decreasing from an interface between the first organic layer and the first inorganic layer in a direction from the first organic layer to the first inorganic layer.

2. The organic light-emitting apparatus as claimed in claim 1, wherein the carbon content of the first inorganic layer ranges from about 0.1% to about 12%.

3. The organic light-emitting apparatus as claimed in claim 1, wherein a Young's modulus of the first inorganic layer gradually increases from the interface between the first organic layer and the first inorganic layer in the direction from the first organic layer to the first inorganic layer.

4. The organic light-emitting apparatus as claimed in claim 3, wherein the Young's modulus of the first inorganic layer is about 110 GPa to about 1000 GPa.

5. The organic light-emitting apparatus as claimed in claim 1, wherein a density of the first inorganic layer gradually increases from the interface between the first organic layer and the first inorganic layer in the direction from the first organic layer to the first inorganic layer.

6. The organic light-emitting apparatus as claimed in claim 1, wherein a thickness of the first inorganic layer is about 50 nm or less.

7. The organic light-emitting apparatus as claimed in claim 1, wherein the encapsulation layer further comprises:
a second organic layer provided on the first inorganic layer; and
a second inorganic layer provided on the second organic layer and including carbon, a carbon content of the second inorganic layer gradually decreasing from an interface between the second organic layer and the second inorganic layer in a direction from the second organic layer to the second inorganic layer.

8. The organic light-emitting apparatus as claimed in claim 7, wherein a thickness of the second inorganic layer is about 50 nm or less.

9. The organic light-emitting apparatus as claimed in claim 1, wherein the first inorganic layer includes AlOₓ, SiNₓ, SiOₓ, SiCₓ, SiOₓN_{y}, or a polysilazane.

10. The organic light-emitting apparatus as claimed in claim 1, wherein the first inorganic layer is formed by an atomic layer deposition (ALD) process.

11. The organic light-emitting apparatus as claimed in claim 1, further comprising a protection layer provided between the organic light-emitting device and the encapsulation layer.

12. A method of manufacturing an organic light-emitting apparatus, comprising:
preparing a substrate provided with an organic light-emitting device including a first electrode, a second electrode, and an intermediate layer provided between the first electrode and the second electrode; and
forming an encapsulation layer to cover the organic light-emitting device, the forming of the encapsulation layer including:
forming a first organic layer to cover the organic light-emitting device; and
forming a first inorganic layer including carbon on the first organic layer, a carbon content of the first inorganic layer gradually decreasing from an interface between the first organic layer and the first inorganic layer in a direction from the first organic layer to the first inorganic layer.

13. The method as claimed in claim 12, wherein the carbon content of the first inorganic layer ranges from about 0.1% to about 12%.

14. The method as claimed in claim 12, wherein a Young's modulus of the first inorganic layer gradually increases from the interface between the first organic layer and the first inorganic layer in the direction from the first organic layer to the first inorganic layer.

15. The method as claimed in claim 12, wherein a thickness of the first inorganic layer is about 50 nm or less.

16. The method as claimed in claim 12, wherein the first inorganic layer is formed by an atomic layer deposition (ALD) process.

17. The method as claimed in claim 16, wherein the ALD process includes a cycling process of an adsorption operation, a first exhaust operation, a reaction operation, and a second exhaust operation.

18. The method as claimed in claim 17, wherein the carbon content of the first inorganic layer is controlled in the reaction operation.

19. The method as claimed in claim 18, further comprising controlling a reaction time in the reaction operation.

20. The method as claimed in claim 12, wherein the first inorganic layer is formed by a plasma-enhanced chemical vapor deposition (PECVD) process.
